(19) United States
(12) Patent Application Publication
(10) Pub. No.: US 2026/0176085 A1
(43) Pub. Date: Jun. 25, 2026

(54) SUBSTRATE TRANSFER APPARATUS AND METHOD

(71) Applicant: Absolics Inc., Covington, GA (US)

(72) Inventors: Chaemook LIM, Covington, GA (US); SUKWAN YOO, Covington, GA (US); BYUNGJOO PARK, Covington, GA (US); MINHO JI, Covington, GA (US); Hyunsik YOON, Covington, GA (US)

(73) Assignee: Absolics Inc., Covington, GA (US)

(21) Appl. No.: 19/426,085

(22) Filed: Dec. 19, 2025

Related U.S. Application Data
(60) Provisional application No. 63/736,581, filed on Dec. 19, 2024.

(51) Int. Cl. B65G 47/248

(52) U.S. Cl. CPC B65G 47/248

(57) ABSTRACT

The present invention relates to a substrate transfer apparatus and method, and the substrate transfer apparatus according to one aspect of the present invention includes a lower stage that supports a lower surface of a substrate and moves the substrate upward, and an upper stage that suctions an upper surface of the substrate moved upward by the lower stage and inverts the substrate.

### CROSS-REFERENCE TO RELATED APPLICATION

This application claims the priority of U.S. Provisional Ser. No. 63/736,581 , filed Dec. 19, 2024, the entire disclosures of which are incorporated herein by reference for all purposes.

### BACKGROUND

### 1. Field

The present invention relates to a substrate transfer apparatus and method, and more particularly, to a substrate transfer apparatus and method for inverting a glass substrate and transferring the inverted substrate to a process.

### 2. Description of the Related Art

Recently, glass substrates have been attracting attention as a replacement for conventional organic substrates in the semiconductor packaging field. Compared to conventional organic substrates, glass substrates offer higher thermal conductivity and a smooth surface, enabling excellent processability into large rectangular panels to make the glass substrates suitable for implementing ultra-fine linewidth semiconductor packaging, and providing advantages such as reducing substrate thickness and lowering power consumption by eliminating the need for an intermediate substrate.

Meanwhile, unlike organic substrates that process both top and bottom surfaces simultaneously, glass substrates require separate processing of the top and bottom surfaces due to their material properties. Consequently, when manufacturing glass substrate semiconductor packages, a substrate inversion operation should precede processing of the glass substrate, in which the glass substrate is rotated such that the top or bottom surface of the glass substrate faces upward depending on whether the processing surface is the top or bottom surface of the glass substrate.

In this regard, substrate transfer technologies including a flipper that grasps and inverts the substrate are being disclosed. These existing technologies have limitations in that the horizontal position of the substrate changes after inversion of the substrate, or only the substrate inversion function is provided, making flexible adaptation to changes in process or inspection operations difficult.

Specifically, the conventional technology disclosing a flipper in which the horizontal position of the substrate changes after inversion of the substrate requires that the position of the configuration receiving the substrate varies depending on whether the substrate is inverted. Therefore, it is difficult to selectively invert some of the substrates after connection to the equipment.

The conventional technology disclosing a flipper that inverts the substrate by rotating the substrate in place does not consider alignment of the substrate before or after inversion of the substrate, which causes a problem in that a separate device for aligning the substrate prior to equipment loading is required. In addition, when the position of the substrate suctioned for inversion is inappropriate, the substrate may detach during inversion.

### RELATED ART DOCUMENTS

### Patent Documents

Korean Patent Application No. 10-2020-0028159
Korean Patent Application No. 10-2021-7034672
Korean Patent Application No. 10-2011-0015996

### SUMMARY

In one aspect, a substrate transfer apparatus and a method that enable double-sided processing and inspection of the substrate through a substrate alignment function and a substrate inversion function are provided.

The objects of the present invention are not limited to the above-described objects, and other objects not described above will be clearly understood from the following description by those skilled in the art.

A substrate transfer apparatus according to one aspect of the present invention includes a lower stage that supports a lower surface of a substrate and moves the substrate upward, and an upper stage that suctions an upper surface of the substrate moved upward by the lower stage and inverts the substrate.

A substrate transfer method according to another aspect of the present invention relates to a substrate transfer method performed by a substrate transfer apparatus including a lower stage that supports a lower surface of a substrate and moves the substrate upward, and an upper stage that suctions an upper surface of the substrate moved upward by the lower stage and inverts the substrate. The method includes loading a substrate on the lower stage, aligning the substrate on the lower stage so that the substrate is positioned at a preset target position, moving the substrate on the lower stage upward, suctioning the substrate by the upper stage, and inverting the substrate by the upper stage.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a perspective view of a substrate transfer apparatus according to one embodiment of the present invention;

FIG. 2 is a perspective view illustrating a lower stage and an upper stage in the substrate transfer apparatus according to one embodiment of the present invention;

FIG. 3 is a front view illustrating a substrate alignment operation state of the lower stage in FIG. 2;

FIG. 4 is a front view illustrating a vertical movement operation state of the lower stage in FIG. 2;

FIG. 5 is a front view illustrating a substrate inversion operation state of the upper stage in FIG. 2; and

FIG. 6 is a flowchart of a substrate transfer method according to another embodiment of the present invention.

### DETAILED DESCRIPTION OF EXEMPLARY EMBODIMENTS

The advantages and features of the present invention and methods for achieving them will become apparent from the following embodiments, which are described in detail with reference to the accompanying drawings. However, the present invention is not limited to the embodiments described below and may be implemented in various other forms. The embodiments are merely provided to fully disclose the present invention and to fully convey the scope of the invention to those skilled in the art, and the present invention is defined only by the claims. Meanwhile, the terms used in the present specification are intended to describe the embodiments, not to limit the present invention. In the present specification, the singular shall include the plural unless the context requires otherwise.

The present invention relates to a technology for transferring a substrate to equipment.

In particular, embodiments of the present invention have a technical feature of stably suctioning and inverting the substrate and feeding the inverted substrate aligned at the correct position into the equipment.

The technical feature may be achieved by a configuration that aligns the substrate at a target position, moves the substrate to an upper portion, and inverts the substrate on the same vertical line as the target position.

Hereinafter, a substrate transfer apparatus according to one embodiment of the present invention will be described in detail with reference to the accompanying drawings.

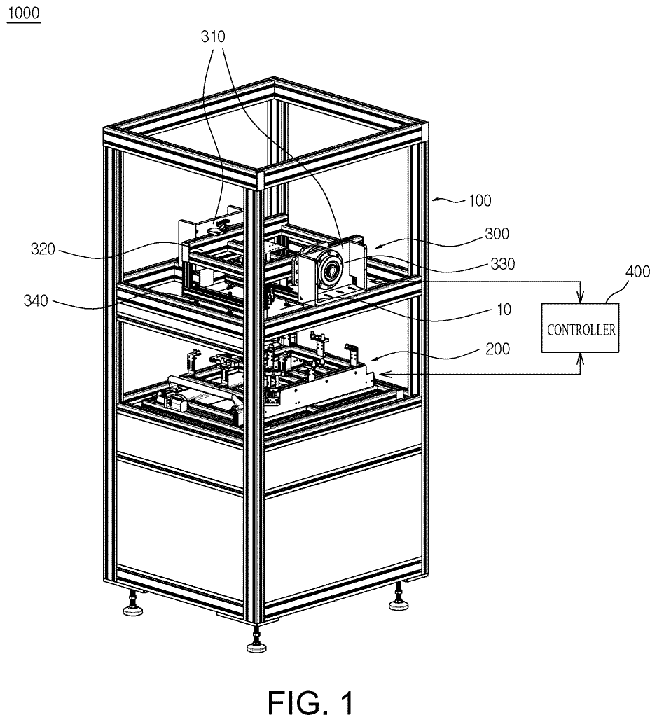

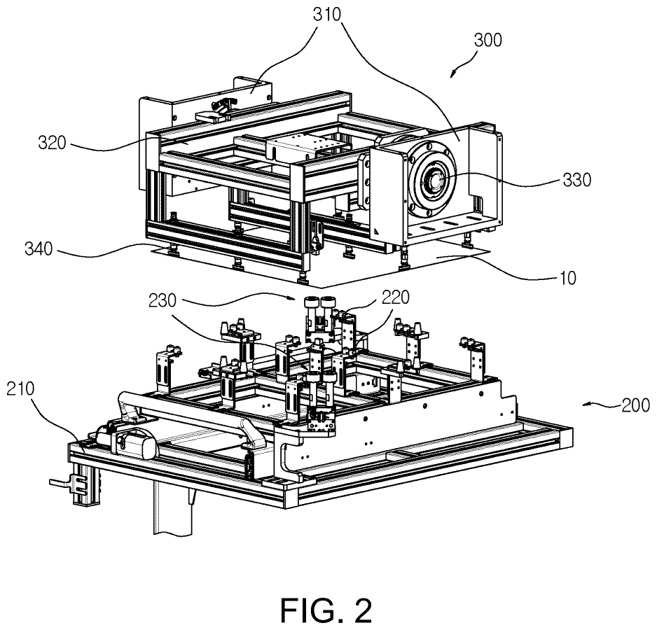

Referring to FIGS. 1 and 2, a substrate transfer apparatus 1000 according to one embodiment of the present invention includes a main frame 100, a lower stage 200, an upper stage 300, and a controller 400.

The main frame 100 may have an accommodating space formed therein.

In a lower portion of the accommodating space of the main frame 100, the lower stage 200 may be installed to be vertically movable and in an upper portion of the accommodating space of the main frame 100, the upper stage 300 may be installed.

The lower stage 200 may support a lower surface of a loaded substrate 10 and move the substrate 10 upward.

The lower stage 200 may include a lifting frame 210, a substrate supporting unit 220, and a substrate aligner 230.

The lifting frame 210 may be installed to be vertically movable in the lower portion of the main frame 100.

Although not specifically illustrated in the drawings, the lifting frame 210 may include LM guides and a servo motor and may be installed to be vertically movable in the lower portion of the main frame 100.

The substrate supporting unit 220 may be installed on an upper portion of the lifting frame 210 to support the lower surface of the loaded substrate 10.

A plurality of substrate supporting units 220 may be provided at intervals on the same horizontal plane to form a region for supporting the substrate 10.

In this case, the substrate supporting unit 220 may be formed of ball casters to prevent surface friction during substrate alignment and allow the substrate 10 to move horizontally by rolling friction.

The substrate aligner 230 may be installed on the upper portion of the lifting frame 210 to move the substrate loaded on the substrate supporting unit 220 to a preset target position for alignment.

The substrate aligner 230 may be provided along the periphery of a region formed by the substrate supporting unit 220, move back and forth on a horizontal plane, and align the substrate 10 loaded on the substrate supporting unit 220 to be positioned at a preset target position.

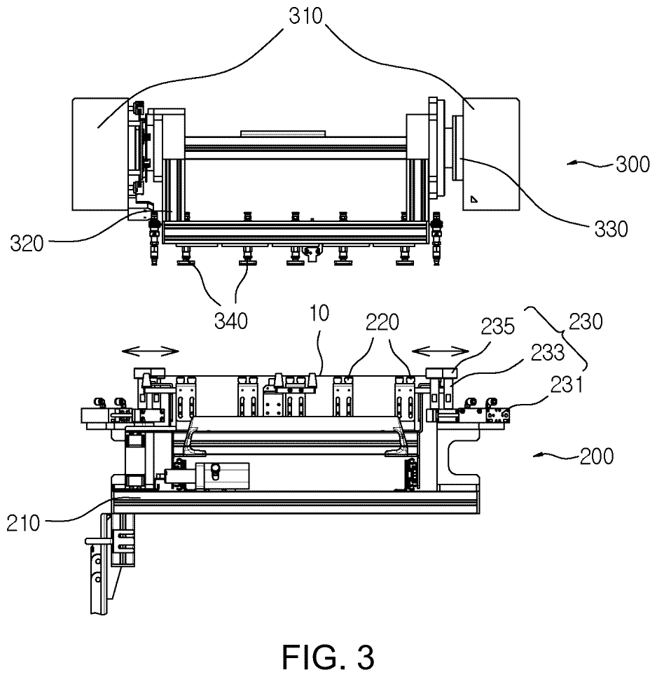

Referring to FIG. 3, the substrate aligner 230 may include a cylinder 231, a moving bar 233, and an alignment roller 235.

The cylinders 231 may be respectively installed to be vertically movable at two opposing points on an outermost line of a preset target position on the upper portion of the lifting frame 210.

Here, the target position may be preset by a user as a range extending the ideal substrate position by a predetermined error margin, for example, 0.5 mm.

The moving bar 233 may be connected to a rod of the cylinder 231 and move back and forth toward a center of a target position according to the operation of the cylinder 231.

A pair of alignment rollers 235 may be spaced apart at a predetermined angle on one end side and the other end side of the moving bar 233 and may come into contact with edges of the substrate 10.

The upper stage 300 may suction an upper surface of the substrate 10 moved upward by the lower stage 200 and invert the substrate 10.

The upper stage 300 may include support frames 310, a rotating frame 320, a driving device 330, and a suction pad 340.

The support frames 310 may be respectively provided on both sides of the upper portion of the main frame 100.

The rotating frame 320 may be rotatably provided on the support frame 310.

Both sides of the rotating frame 320 may be rotatably installed on the support frames 310 and may rotate in place back and forth at the upper portion of the main frame 100.

The driving device 330 may generate rotational power to rotate the rotating frame 320.

The suction pad 340 may be provided on a lower portion of the rotating frame 320 and may suction the substrate 10 moved upward by the lower stage 200.

A plurality of suction pads 340 may be provided at intervals on the same horizontal plane at positions corresponding to the substrate supporting unit 220 to stably suction the substrate 10.

The controller 400 may control the operations of the lower stage 200 and the upper stage 300.

The controller 400 may control the operation of the lower stage 200 such that when the substrate is loaded on the lower stage 200, the lower stage 200 aligns the position of the substrate and moves the substrate upward. In addition, the controller 400 may control the operation of the upper stage 300 to suction the substrate 10 in response to the lower stage 200 moving the substrate 10 upward. Also, the controller 400 may control the operation of the lower stage 200 to move downward in response to the upper stage 300 suctioning the substrate 10, and may control the operation of the upper stage 300 to invert the substrate 10 in response to the lower stage 200 moving downward.

A substrate transfer method according to another embodiment of the present invention may be performed by the substrate transfer apparatus 1000 according to one embodiment of the present invention.

Hereinafter, for convenience of description, identical reference numerals are used for functionally corresponding components and redundant descriptions will be omitted.

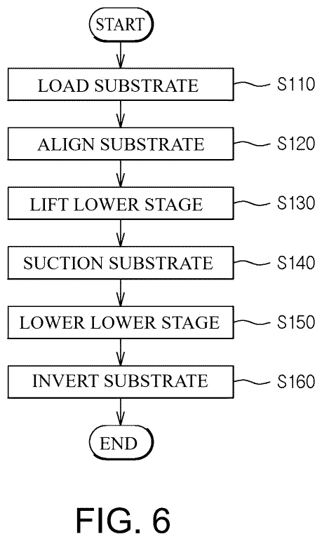

Referring to FIG. 6, the substrate transfer method according to another embodiment of the present invention may include a substrate loading operation S110, a substrate alignment operation S120, a lower stage lifting operation S130, a substrate suction operation S140, a lower stage lowering operation S150, and a substrate inversion operation S160.

The substrate loading operation S110 may be an operation in which a substrate 10 is loaded on a lower stage 200 by a robot hand that grips and transfers each loaded substrate.

Referring to FIG. 3, the substrate alignment operation S120 may be an operation of aligning the substrate 10 loaded on the lower stage 200 so that the substrate 10 is positioned at a preset target position on a horizontal plane.

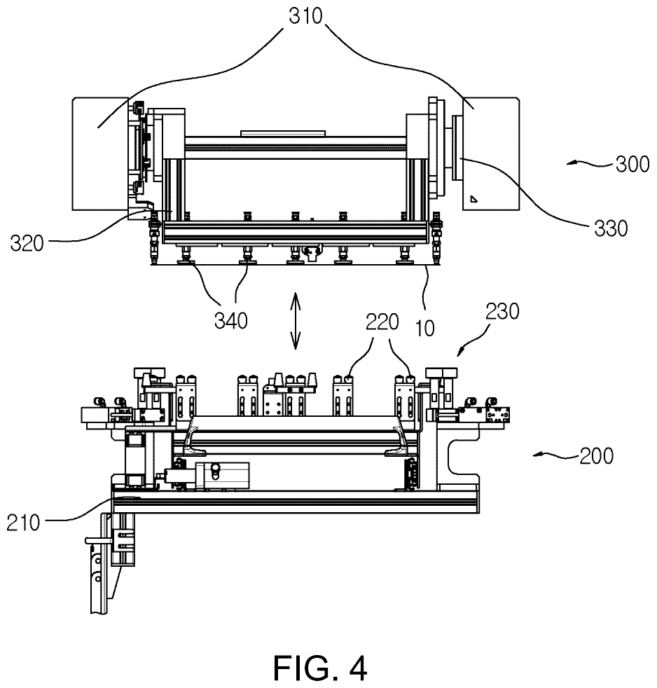

Referring to FIG. 4, in the lower stage lifting operation S130, the lower stage 200 may move the substrate 10 upward. In the substrate suction operation S140, an upper stage 300 may suction an upper surface of the substrate 10 moved upward by the lower stage 200, and in the lower stage lowering operation S150, the lower stage 200 may move downward to provide a space for the upper stage 300 to invert the substrate 10.

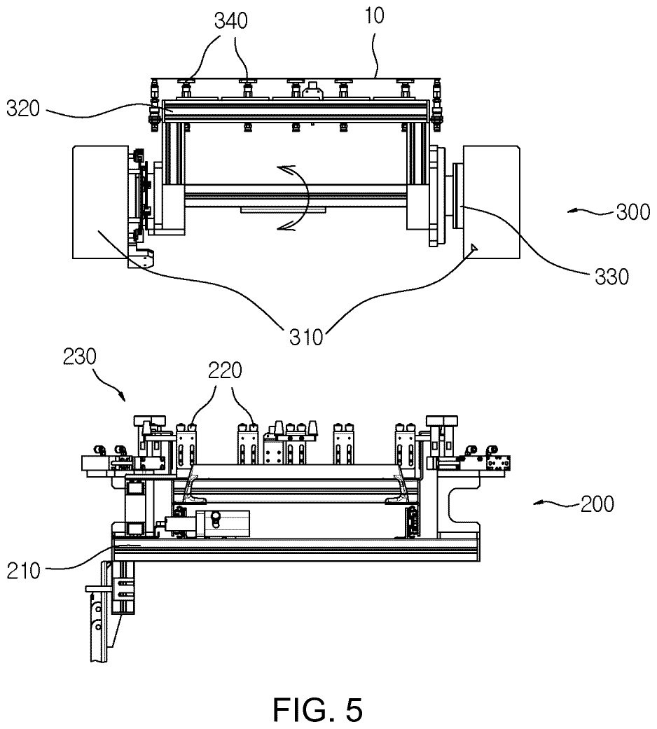

Referring to FIG. 5, in the substrate inversion operation S160, the upper stage 300 may rotate the substrate 10 180 degrees vertically while suctioning the substrate 10, thereby inverting the substrate 10 so that a lower surface of the substrate 10 faces upward.

According to the above configuration, a substrate may be stably suctioned, and the substrate that is aligned and inverted at a target position may be provided to equipment.

In addition, since substrate alignment and substrate inversion are performed on the same vertical line, there is an advantage of providing both substrate alignment and substrate inversion functions within a relatively small area.

Accordingly, the convenience of processing and inspecting both sides of a glass substrate may be improved.

According to the embodiments of the present invention, a substrate alignment and a substrate inversion are performed on the same vertical line, thereby reducing the space required for transfer and improving transfer efficiency.

In addition, when a substrate is aligned and gripped, an effect of improving the stability of gripping and inverting the substrate is achieved. Accordingly, an effect of improving the convenience of processing and inspecting both sides of the substrate can be expected.

The effects of the present invention are not limited to the effects described above, and other effects not described herein can be clearly understood by those skilled in the art from the description of the claims.

Those skilled in the art to which the present invention pertains will understand that the present invention may be embodied in various other specific forms without altering the technical spirit or essential characteristics of the invention. Therefore, the embodiments described above are to be understood as illustrative in all respects and not restrictive. The scope of the present invention is defined by the claims below rather than the detailed description above, and all modifications or variations derived from the claims and their equivalent concepts should be interpreted as being included within the scope of the present invention.

What is claimed is:

1. A substrate transfer apparatus comprising:
a lower stage that supports a lower surface of a substrate and moves the substrate upward; and
an upper stage that suctions an upper surface of the substrate moved upward by the lower stage and inverts the substrate.

2. The substrate transfer apparatus of claim 1, further comprising a main frame in which the lower stage is installed on a lower portion to be vertically movable and the upper stage is installed on an upper portion.

3. The substrate transfer apparatus of claim 2, wherein the lower stage includes:
a lifting frame installed on the lower portion of the main frame to be vertically movable;
a substrate supporting unit installed on an upper portion of the lifting frame to support a lower surface of a loaded substrate; and
a substrate aligner installed on the upper portion of the lifting frame to move the substrate loaded on the substrate supporting unit to a preset target position for alignment.

4. The substrate transfer apparatus of claim 3, wherein the substrate aligner includes:
cylinders installed respectively at two opposing points on an outermost line of the target position on the upper portion of the lifting frame;
a moving bar connected to a rod of the cylinder and configured to move back and forth toward a center of the target position according to operation of the cylinder; and
a pair of alignment rollers spaced apart at a predetermined angle on one end side and the other end side of the moving bar and coming into contact with edges of the substrate.

5. The substrate transfer apparatus of claim 2, wherein the upper stage includes:
support frames respectively provided on both sides of the upper portion of the main frame;
a rotating frame rotatably installed on the support frame;
a driving device configured to rotate the rotating frame; and
a suction pad provided on a lower portion of the rotating frame and configured to suction the substrate moved upward by the lower stage.

6. A substrate transfer method performed by a substrate transfer apparatus including a lower stage and an upper stage, the method comprising:
loading a substrate on the lower stage;
aligning the substrate on the lower stage so that the substrate is positioned at a preset target position;
moving the substrate on the lower stage upward;
suctioning the substrate by the upper stage; and
inverting the substrate by the upper stage.

7. The substrate transfer method of claim 6, further comprising, between the suctioning of the substrate and the inverting of the substrate, lowering the lower stage to provide a space for the upper stage to invert the substrate.

8. The substrate transfer method of claim 6, wherein the inverting of the substrate includes rotating the substrate 180 degrees vertically by the upper stage while suctioning an upper surface of the substrate to invert the substrate so that a lower surface of the substrate faces upward.
